(19) United States
(12) Patent Application Publication
(10) Pub. No.: US 2026/0297383 A1
(43) Pub. Date: Oct. 1, 2026

(54) POLISHING COMPOSITION AND POLISHING METHOD

(71) Applicant: FUJIMI INCORPORATED, Kiyosu-shi (JP)

(72) Inventors: Ryo Wakabayashi, Kiyosu-shi (JP); Akiko Soumiya, Kiyosu-shi (JP)

(73) Assignee: FUJIMI INCORPORATED, Kiyosu-shi (JP)

(21) Appl. No.: 19/571,798

(22) Filed: Mar. 19, 2026

(30) Foreign Application Priority Data
Mar. 28, 2025 (JP) 2025-055779

(51) Int. Cl. C09G 1/02; H10P 52/40

(52) U.S. Cl. CPC C09G 1/02; H10P 52/402

(57) ABSTRACT

Provided herein are means whereby an object to be polished can be polished at a high polishing removal rate and defects in the surface of the object to be polished after polishing can be reduced. Disclosed herein is a polishing composition containing water and alumina particles, wherein the alumina particles have a bimodal volume-based particle size distribution.

### TECHNICAL FIELD

The present disclosure relates to a polishing composition and a polishing method.

### BACKGROUND ART

In the semiconductor industry, a planarization technique is usually used to increase the flatness of surface of a semiconductor substrate (e.g., a wafer). Chemical mechanical polishing (CMP) is one of planarization techniques commonly used. Chemical mechanical polishing is a method for planarizing the surface of an object to be polished (workpiece to be polished) such as a semiconductor substrate with use of a polishing composition containing abrasive grains such as silica, alumina, or ceria, an anticorrosive, a surfactant, etc.

Meanwhile, substrates containing a resin material (herein also referred to as “resin-containing substrates”) are becoming popular. Therefore, there is a growing need for polishing compositions used for polishing resin-containing substrates.

For example, Japanese Patent Laid-Open No. 2005-268666 (corresponding to U.S. Patent Application Publication No. 2005/204638) discloses a chemical mechanical polishing composition containing alumina, a complexing agent, and an oxidizing agent. The chemical mechanical polishing composition disclosed in Japanese Patent Laid-Open No. 2005-268666 (corresponding to U.S. Patent Application Publication No. 2005/204638) can be used to perform chemical mechanical polishing on a resin layer and a conductor layer containing a metal.

### SUMMARY OF INVENTION

However, the technique disclosed in Japanese Patent Laid-Open No. 2005-268666 (corresponding to U.S. Patent Application Publication No. 2005/204638) was still insufficient to achieve both polishing an object to be polished at a high polishing removal rate and reducing defects in the surface of the object to be polished after polishing.

It is therefore an object of the present disclosure to provide means whereby an object to be polished can be polished at a high polishing removal rate and defects in the surface of the object to be polished after polishing can be reduced.

In order to achieve the above object, the present inventors have intensively studied. As a result, the present inventors have found that the above object can be achieved by a polishing composition containing water and alumina particles, wherein the alumina particles have a bimodal volume-based particle size distribution, and this finding has led to the completion of the present disclosure.

### DESCRIPTION OF EMBODIMENTS

Hereinbelow, embodiments of the present disclosure will be described. The embodiments described herein are merely examples for embodying the technical ideas of the present disclosure and are not intended to limit the present disclosure. Therefore, all other possible forms, methods of use, and operational techniques that can be conceived by those skilled in the art without departing from the spirit of the present disclosure are included in the scope and spirit of the present disclosure and are included in the scope of the invention as defined by the claims and equivalents thereof. The embodiments described herein can be freely combined to form other embodiments.

Unless otherwise specified, operations and measurements of physical properties are herein performed under conditions of room temperature (20° C. or more and 25° C. or less)/relative humidity of 40% RH or more and 50% Rh or less.

A first embodiment of the present disclosure provides a polishing composition containing water and alumina particles, wherein the alumina particles have a bimodal volume-based particle size distribution. The polishing composition of the present embodiment having such a configuration makes it possible to polish an object to be polished at a high polishing removal rate and to reduce defects (especially, scratching) in the surface of the object to be polished after polishing.

Hereinbelow, the present disclosure will be described in detail. It should be noted that the “polishing removal rate” is herein synonymous with “polishing speed” and “polishing rate”.

### Object to be Polished

An object to be polished, to which the polishing composition according to some embodiments of the present disclosure is applied, is not limited but preferably contains a resin material. That is, according to one preferred embodiment, the polishing composition according to the present disclosure is used for polishing an object to be polished containing a resin material. The polishing composition according to the present disclosure is particularly suitable for polishing a substrate having a patterned structure formed of a material containing a resin material, and technical effects of the present disclosure are fully exhibited when such a substrate is polished.

Examples of the resin material contained in the object to be polished include, but are not limited to, polyethylene terephthalate (PET), polybenzoxazole (PBO), polybutylene terephthalate (PBT), polyimide (PI), polyamide (PA), epoxy resin, urethane acrylate resin, unsaturated polyester resin, phenol resin, polynorbornene resin, polyacetal (POM), polycarbonate (PC), modified-polyphenylene ether (m-PPE), ultra-high molecular weight polyethylene (UHMWPE), syndiotactic polystyrene (SPS), amorphous polyarylate (PAR), polysulfone (PSF), polyether sulfone (PES), polyphenylene sulfide (PPS), polyether ether ketone (PEEK), polyether imide (PEI), benzocyclobutene (BCB), fluorine resin, and liquid crystal polymer (LCP). Among them, polyimide (PI), epoxy resin, urethane acrylate resin, or benzocyclobutene (BCB) is preferably contained. The above-mentioned resin materials may be used singly or in combination of two or more of them. According to some embodiments of the present disclosure, the resin material contains polyimide (PI). When polyimide (PI) is contained, desired effects of the present disclosure can be efficiently produced. According to such an embodiment, desired effects of the present disclosure can be efficiently produced.

More preferably, the object to be polished further contains a metallic material in addition to the resin material. The type of the metallic material is not limited, and examples of the metallic material include magnesium (Mg), aluminum (Al), titanium (Ti), chromium (Cr), manganese (Mn), iron (Fe), cobalt (Co), nickel (Ni), copper (Cu), zinc (Zn), zirconium (Zr), gold (Au), silver (Ag), platinum (Pt), iridium (Ir), bismuth (Bi), niobium (Ni), molybdenum (Mo), tin (Sn), tungsten (W), and lead (Pb). Among them, a transition metal (especially, an element in Group 6, Group 9, or Group 11 in the periodic table), an element in Group 13 in the periodic table, or an element in Group 14 in the periodic table is preferably contained, and an element in Group 11 in the periodic table or an element in Group 14 in the periodic table is more preferably contained. The element in Group 11 in the periodic table is more preferably copper (Cu), and the element in Group 14 in the periodic table is more preferably tin (Sn). The metallic material may be, for example, any elemental metal or an alloy of any metallic element and one or more other elements. The above-mentioned metallic materials may be used singly or in combination of two or more of them.

### [Polishing Composition]

### <<Alumina Particles>>

The polishing composition according to the present embodiment contains, as abrasive grains, alumina particles. Abrasive grains mechanically polish an object to be polished and increase a polishing removal rate. The alumina particles have a sufficient hardness and are therefore highly effective at increasing the polishing removal rate of an object to be polished. Further, the alumina particles used in the present disclosure have a bimodal volume-based particle size distribution, which makes it possible to polish an object to be polished (preferably, a resin material) at a high polishing removal rate and to reduce defects (especially, scratching) in the surface of the object to be polished after polishing.

The volume-based particle size distribution is herein a graph with X axis representing the common logarithm to base 10 of a particle size (μm) and Y axis representing a volume frequency (%). The volume-based particle size distribution of the alumina particles can be determined by dynamic light scattering method, laser diffraction, laser scattering, resistive pulse sensing, or the like. The volume-based particle size distribution is herein measured using a laser diffraction particle size distribution measurement apparatus.

The bimodal volume-based particle size distribution means that the graph of the volume-based particle size distribution has two peaks (local maximum values). When, in the volume-based particle size distribution of the alumina particles, the peak on a smaller particle size side is defined as a first peak, and the peak on a larger particle size side than the first peak is defined as a second peak, the ratio of a particle size PS2 at the peak top of the second peak to a particle size PS1 at the peak top of the first peak (PS2/PS1) is preferably 1.3 or more and 3 or less. From the viewpoint of efficiently obtaining the effects of the present disclosure, PS2/PS1 is more preferably 1.6 or more and 2.4 or less, even more preferably 1.8 or more and 2.2 or less.

The particle size PS1 of the alumina particles at the peak top of the first peak is preferably 0.4 μm or more, more preferably 0.43 μm or more, even more preferably 0.45 μm or more. Further, the particle size PS1 is preferably 0.60 μm or less, more preferably 0.58 μm or less, even more preferably 0.55 μm or less. That is, the particle size PS1 of the alumina particles at the peak top of the first peak is preferably 0.4 μm or more and 0.60 μm or less, more preferably 0.43 μm or more and 0.58 μm or less, even more preferably 0.45 μm or more and 0.55 μm or less.

The particle size PS2 of the alumina particles at the peak top of the second peak is preferably 0.80 μm or more, more preferably 0.85 μm or more, even more preferably 0.90 μm or more. Further, the particle size PS2 is preferably 1.20 μm or less, more preferably 1.15 μm or less, even more preferably 1.10 μm or less. That is, the particle size PS2 of the alumina particles at the peak top of the second peak is preferably 0.80 μm or more and 1.20 μm or less, more preferably 0.85 μm or more and 1.15 μm or less, even more preferably 0.90 μm or more and 1.10 μm or less.

When a peak height of the first peak is defined as H1 and a peak height of the second peak is defined as H2, the ratio of the peak height H2 of the second peak to the peak height H1 of the first peak (H2/H1) is preferably 0.1 or more and 1.0 or less. From the viewpoint of efficiently obtaining the effects of the present disclosure, H2/H1 is more preferably 0.2 or more and 0.9 or less, even more preferably 0.3 or more and 0.8 or less.

### <Non-Sphericity N and Skewness S>

The alumina particles used in the present disclosure preferably have a non-sphericity N represented by the following formula (1) and satisfying a relationship of the following formula (2).

$$\begin{matrix}[ Formula 1 ] & \\ Non - sphericity N = \frac{SA}{{SA}^{′}} & ( 1 )\end{matrix}$$

$$2 \leq N \leq 8 \qquad ( 2 )$$

The non-sphericity N represented by the above formula (1) is a parameter indicating the degree of distortion in the outer shape of the particles relative to a perfect sphere having a comparable particle size, and as the non-sphericity N becomes larger than 1, the degree of distortion in the shape of the particles becomes higher. When the non-sphericity N is 1, the particles are perfectly spherical. The alumina particles used in the present embodiment have a non-sphericity N of 2 or more and 8 or less, and therefore the degree of distortion in their shape is high.

Further, the alumina particles preferably have a skewness S represented by the following formula (3) and satisfying a relationship of the following formula (4).

$$\begin{matrix}[ Formula 2 ] & \\ Skewness S = \frac{( {D}_{50} / {D}_{2} )}{( {D}_{98} / {D}_{50} )} & ( 3 )\end{matrix}$$

$$0.5 \leq S \leq 1. \qquad ( 4 )$$

The skewness S represented by the above formula (3) is a parameter indicating the symmetricalness (degree of skew) of particle size distribution of the alumina particles. When the skewness S is less than 1 (S<1), the particle size distribution of the alumina particles is biased toward a larger particle size side, which means that the amount of the alumina particles having a large particle size is relatively large. On the other hand, when the skewness S exceeds 1 (1<S), the particle size distribution of the alumina particles is biased toward a smaller particle size side, which means that the amount of the alumina particles having a small particle size is relatively large. When the skewness S is 1 (S=1), the particle size distribution of the alumina particles is symmetrical, that is, the particle size distribution of the alumina particles is a lognormal distribution. The alumina particles used in the present embodiment have a skewness S of 0.50 or more and 1.00 or less, and therefore the particle size distribution thereof is biased toward a larger particle size side (the amount of the particles having a large particle size is relatively large) or is symmetrical.

It is commonly known that when abrasive grains have a relatively large size, a polishing removal rate is high and that when the degree of shape distortion or the aspect ratio of abrasive grains is high, a polishing removal rate is high. However, when abrasive grains have a relatively large size or a high non-sphericity or aspect ratio, defects such as scratching in the surface of an object to be polished after polishing are increased. On the other hand, when abrasive grains have a relatively small size, a polishing removal rate is low, but defects such as scratching in the surface of an object to be polished after polishing tend to be improved. Further, it is known that when spherical particles are used, a polishing removal rate is relatively lower, but defects such as scratching in the surface of an object to be polished after polishing are reduced as compared to when non-spherical particles are used. As described above, an increase in polishing removal rate and the occurrence of defects such as scratching are in a trade-off relationship.

However, as a result of intensive study, the present inventors have found that a polishing composition, which contains alumina particles that satisfy at least one of a requirement that a non-sphericity N represented by the above formula (1) satisfies a relationship of the above formula (2) and a requirement that a skewness S represented by the above formula (3) satisfies a relationship of the above formula (4), makes it possible to further increase the polishing removal rate of an object to be polished (preferably, a resin material) and to further reduce defects in the surface of a polished object (preferably, a resin material). That is, the present inventors have found that a polishing composition, which contains alumina particles that satisfy at least one of a requirement that a non-sphericity N represented by the above formula (1) satisfies a relationship of the above formula (2) and a requirement that a skewness S represented by the above formula (3) satisfies a relationship of the above formula (4), makes it possible to more efficiently exhibit the effects of the present disclosure.

### (Non-Sphericity N)

When the non-sphericity N of the alumina particles, which is represented by the above formula (1), satisfies a relationship of the above formula (2), the polishing removal rate of an object to be polished (preferably, a resin material) is further increased and defects (especially, scratching) in the surface of a polished object (preferably, a resin material) are further reduced. The non-sphericity N of the alumina particles is more preferably 2.5 or more and 7.5 or less, even more preferably 3.0 or more and 7.0 or less.

The BET specific surface area SA of the alumina particles, which is used to calculate the non-sphericity N, is a specific surface area measured on the basis of JIS Z8830:2013. More specifically, the BET specific surface area SA can be measured by a method which will be described in Examples.

The theoretical specific surface area SA′ of the alumina particles is a value calculated by the following formula (5) using a value of D₅₀ used to calculate the above skewness S.

$$\begin{matrix}[ Formula 3 ] & \\ Theoretical specific surface area {SA}^{′} = \frac{6}{ρ \times {D}_{50}} & ( 5 )\end{matrix}$$

In the above formula (5), ρ represents a density of the alumina particles and is defined as 3.95 g/cm³.

### (Skewness S)

When the skewness S of the alumina particles represented by the above formula (3) satisfies a relationship of the above formula (4), the polishing removal rate of an object to be polished (preferably, a resin material) is further increased and defects (especially, scratching) in the surface of a polished object (preferably, a resin material) are further reduced. The skewness S of the alumina particles is more preferably 0.55 or more and 0.95 or less, even more preferably 0.60 or more and 0.90 or less.

D₂, D₅₀, and D₉₈ of the alumina particles, which are used to calculate the skewness S, can be determined by the above-described method for measuring a particle size distribution such as dynamic light scattering method, laser diffraction, laser scattering, or resistive pulse sensing. Herein, values determined as particle sizes at which cumulative frequencies from a smaller particle size side in a volume-based particle size distribution measured using a laser diffraction particle size distribution measurement apparatus are 2%, 50%, and 98% are respectively used as D₂, D₅₀, and D₉₈. More specifically, D₂, D₅₀, and D₉₈ can be measured by a method which will be described in Examples.

The shape of the alumina particles is not limited as long as the alumina particles have a bimodal volume-based particle size distribution. The shape of the alumina particles may be, for example, any one of various shapes such as a polygonal prism shape (e.g., a triangular prism shape or a quadrangular prism shape), a circular cylindrical shape, a barrel-like shape that is a circular cylindrical shape whose central portion is thicker than its end portions, a donut-like shape that is a disc shape having a through-hole in its central portion, a plate shape, a so-called cocoon-like shape having a constriction in its central portion, a so-called associated spherical shape in which a plurality of particles are integrated, a so-called Konpeito (which is a star-shaped sugar candy)-like shape having a plurality of projections on its surface, a rugby ball-like shape, a conical shape, a truncated conical shape, a polygonal pyramidal shape, a polygonal truncated pyramidal shape, a semi-spherical shape, a needle-like shape, and an indefinite shape.

### <D₅₀>

The D₅₀ of the alumina particles is not limited. For example, the D₅₀ of the alumina particles is preferably 2.0 μm or less, more preferably 1.5 μm or less, even more preferably 1.3 μm or less, particularly preferably 1.0 μm or less, most preferably 0.9 μm or less. The D₅₀ of the alumina particles is preferably 0.05 μm or more, more preferably 0.1 μm or more, even more preferably 0.3 μm or more, particularly preferably 0.4 μm or more, most preferably 0.5 μm or more. When the D₅₀ of the alumina particles is within the above range, it is possible to achieve a better balance between increasing the polishing removal rate of an object to be polished (preferably, a resin material) and reducing defects (especially, scratching) in the surface of the object to be polished after polishing. The D₅₀ of the alumina particles is, for example, preferably 0.05 μm or more and 2.0 μm or less, more preferably 0.1 μm or more and 1.5 μm or less, even more preferably 0.3 μm or more and 1.3 μm or less, particularly preferably 0.4 μm or more and 1.0 μm or less, most preferably 0.5 μm or more and 0.9 μm or less.

### <α-Phase Content>

The alumina particles preferably have an α phase, which is a preferred crystal structure for polishing abrasive grains, or a crystal phase in a transition state to an α phase, such as a θ phase, a δ phase, or a γ phase. The alumina particles more preferably have an α phase or a θ phase and even more preferably have an α phase. In regard to an α phase, it is considered that there is a more preferred range for the degree of phase transition to α phase.

In general, an α-phase crystal structure is believed to be hardest, but when particles are sufficiently sintered at high temperature for phase transition to α phase, it is estimated that the shape of the particles is changed to be circular so that polishing performance is degraded. An α-phase content can be used as a reference that indicates the degree of an ox phase that the alumina particles have. The lower limit of the α-phase content is preferably 50% or more. The lower limit of the α-phase content is more preferably 60% or more, even more preferably 70% or more, still even more preferably 80% or more, particularly preferably 90% or more. The upper limit of the α-phase content is preferably 100% or less. The upper limit of the α-phase content is more preferably 98% or less. That is, the α-phase content of the alumina particles is preferably 50% or more and 100% or less, more preferably 60% or more and 98% or less, even more preferably 80% or more and 98% or less.

When the α-phase content is within the above preferred range, polishing power is expected to increase, that is, the polishing removal rate of an object to be polished (preferably, a resin material) is expected to further increase. It should be noted that the α-phase content of the alumina particles can be calculated from the integrated intensity ratio between peaks at 2θ=43°±2° corresponding to a (113) plane which are obtained by subjecting a reference material and a measurement sample to X-ray diffraction measurement using Cu-Kα radiation.

### <Concentration (Content)>

The concentration (content) of the alumina particles in the polishing composition is not limited, but is preferably 0.01% by mass or more, more preferably 0.1% by mass or more, even more preferably 0.5% by mass or more, particularly preferably 1% by mass or more, particularly preferably 1.5% by mass or more relative to the total mass of the polishing composition. As the concentration of the alumina particles increases, a polishing removal rate increases. The concentration (content) of the alumina particles is preferably 25% by mass or less, more preferably 15% by mass or less, even more preferably 10% by mass or less, still even more preferably less than 9% by mass, particularly preferably 8% by mass or less relative to the total mass of the polishing composition. When the concentration (content) of the alumina particles is within the above range, it is possible to further increase the polishing removal rate of an object to be polished (preferably, a resin material). In addition, there is an effect that the occurrence of defects such as scratching in the surface of an object to be polished (preferably, a resin material) after polishing is further reduced. The concentration (content) of the alumina particles is, for example, preferably 0.01% by mass or more and 25% by mass or less, more preferably 0.1% by mass or more and 15% by mass or less, even more preferably 0.5% by mass or more and 10% by mass or less, still even more preferably 1% by mass or more and less than 9% by mass, particularly preferably 1.5% by mass or more and 8% by mass or less relative to the total mass of the polishing composition.

A method for producing the alumina particles having a bimodal distribution is not limited, and may be, for example, a method in which two types of alumina particles different in particle size distribution are mixed. A method for mixing the alumina particles is not limited, either, and a publicly-known method, such as dry blending or wet blending, may be appropriately used.

Alternatively, the method for producing the alumina particles having a bimodal distribution may be a method in which a powder obtained by firing a starting material, such as an aluminum oxide precursor powder, is appropriately ground and/or classified. This method makes it possible to efficiently obtain alumina particles having non-sphericity N and skewness S respectively satisfying a relationship of the above formula (2) and a relationship of the above formula (4).

The aluminum oxide precursor powder may be an aluminum hydroxide powder or an aluminum oxide powder having a transitional aluminum oxide phase. The aluminum hydroxide powder may be gibbsite, boehmite, pseudo-boehmite, diaspore, or any combination of two or more of them. The aluminum oxide precursor powder may contain gamma (γ), eta (η), theta (θ), chi (χ), kappa (κ), and/or delta (δ)-phase aluminum oxide.

By firing the above aluminum oxide precursor powder, aluminum oxide (alumina) can be formed. A firing method is not limited, and may be, for example, a method using a rotary kiln, a tunnel kiln, an electric furnace, a muffle furnace, an elevator kiln, or a pusher kiln. A firing temperature may be 700° C. or higher and 1600° C. or lower, and a firing time may be 1 hour or more and 48 hours or less. This makes it possible to obtain α-alumina having a suitable-phase content. When the firing temperature is higher, a specific surface area tends to become smaller.

By appropriately grinding and classifying the fired alumina powder, it is possible to obtain alumina having a desired particle size distribution. The grinding and classifying can be performed by a wet process or a dry process.

A grinding method may be, for example, a method using a grinding apparatus. The grinding apparatus may be, for example, a publicly-known apparatus such as a ball mill, a bead mill, a planetary mill, a vibration mill, a colloid mill, a conical mill, a disk mill, an edge mill, a gristmill, a hammer mill, a mortar, a pellet mill, a VSI mill, a Wiley mill, a roller mill, a jet mill, a homomixer, a high-pressure homogenizer, or an ultrasonic apparatus. By changing the condition, such as grinding time, of grinding in each of such apparatuses, it is possible to obtain alumina having a desired particle size distribution.

A classification method may be, for example, any of various methods such as filtering (filtration), sieving, air classification, elutriation classification, weight classification, inertial classification, and centrifugal classification. Examples of the filtering include coarse filtration, microfiltration, ultrafiltration, and reverse osmosis, and various filtration techniques can be used. Examples of a filter used for the filtering include a mesh filter, a depth filter, and a membrane filter. By adjusting a filtration time, a filtration speed, and a filtration accuracy in the filtering, it is possible to control the particle size distribution of the powder. For example, the filtration accuracy may be 0.1 μm or more and 300 μm or less.

By appropriately selecting and/or combining one or more of the above-described firing method, grinding method, and classification/filtering method and controlling its or their respective conditions, it is possible to obtain alumina particles having a bimodal distribution (preferably alumina particles having non-sphericity N and skewness S respectively satisfying a relationship of the above formula (2) and a relationship of the above formula (4)).

It should be noted that the alumina particles may be a commercially-available product.

### <<Water>>

The polishing composition according to the present disclosure contains water. The water disperses or dissolves each component. From the viewpoint of preventing the effect of impurities on other components of the polishing composition, it is preferred that water having purity as high as possible be used. Specifically, preferred is ion-exchange water (deionized water), pure water or ultrapure water obtained by removing impurity ions with use of an ion exchange resin and then removing foreign matters with use of a filter, or distilled water. For the purpose of controlling the dispersibility of other components in the polishing composition, an organic solvent as a dispersing medium may be further contained.

### <<Other Components>>

The polishing composition according to the present disclosure may further contain publicly-known other components such as a pH adjusting agent, a surfactant, a dispersing agent, a thickening agent (viscosity adjusting agent), a surface protecting agent, a wetting agent, an oxidizing agent, a water-soluble polymer, a salt, an anticorrosive, an antiseptic agent, and an antifungal agent to the extent that the effects of the present disclosure are not impaired. The content of each of the other components may be appropriately set depending on the purpose of its addition. Hereinbelow, a pH adjusting agent, a surfactant, a dispersing agent, a thickening agent (viscosity adjusting agent), an oxidizing agent, an anticorrosive, an antiseptic agent, and an antifungal agent will be described. Further, a chelating agent will be also described.

### <pH Adjusting Agent>

The polishing composition according to some embodiments of the present disclosure may further contain a pH adjusting agent. The pH adjusting agent can contribute to adjusting the pH of the polishing composition by selecting the type and amount thereof to be added.

The pH adjusting agent is not limited as long as it is a compound having the function of adjusting pH, and may be a publicly-known compound. The pH adjusting agent is not limited as long as it has the function of adjusting pH, and may be, for example, an acid or an alkali.

The acid to be used may be either an inorganic acid or an organic acid. Examples of the inorganic acid include, but are not limited to, sulfuric acid, nitric acid, boric acid, carbonic acid, hypophosphorous acid, phosphorous acid, and phosphoric acid. Examples of the organic acid include, but are not limited to, carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, methanesulfonic acid, ethanesulfonic acid, and isethionic acid. Among them, preferred are organic acids and more preferred are malic acid, citric acid, and maleic acid. It should be noted that when an inorganic acid is used, preferred are nitric acid, sulfuric acid, and phosphoric acid.

Examples of the alkali include, but are not limited to, a salt of an alkali metal, a salt of an alkaline-earth metal, a quaternary ammonium, and ammonia.

Specific examples of the alkali metal include potassium and sodium. Specific examples of the alkaline-earth metal include calcium and strontium. Specific examples of the salt include a hydroxide salt, a carbonate, a hydrogencarbonate, a sulfate, and an acetate. Specific examples of the quaternary ammonium include tetramethyl ammonium, tetraethyl ammonium, tetrabutyl ammonium and hydroxides thereof. Among these alkalis, preferred are potassium carbonate, potassium hydroxide, and ammonia.

These pH adjusting agents may be used singly or in combination of two or more of them.

The pH of the polishing composition according to some embodiments of the present disclosure is not limited, but the polishing composition is preferably alkaline, that is, the pH is preferably 7 or more from the viewpoint of a polishing removal rate. The pH may be 8 or more, 9 or more, 10 or more, or 11 or more. From the viewpoint of further increasing the polishing removal rate of an object to be polished (preferably, a resin material) and further reducing defects, the pH is preferably 14 or less and may be 13 or less, 12 or less, 11.5 or less, or 11 or less. For example, the pH of the polishing composition can be set to 7 or more and 14 or less and may be 7 or more and 13 or less or 7 or more and 12 or less. When the pH of the polishing composition is within the above range, there is an effect that a better balance can be achieved between increasing the polishing removal rate of an object to be polished (preferably, a resin material) and reducing defects (especially, scratching). The content of the pH adjusting agent is not limited, but is preferably set so that the value of pH can fall within the above preferred range. It should be noted that the pH of the polishing composition can be measured by, for example, a pH meter.

### <Surfactant>

The polishing composition according to some embodiments of the present disclosure may contain a surfactant. The surfactant that may be contained in the polishing composition of the present disclosure is at least one selected from the group consisting of an anionic surfactant, a cationic surfactant, an ampholytic surfactant, and a nonionic surfactant. Among them, the surfactant contained in the polishing composition is preferably a nonionic surfactant. These surfactants may be used singly or in combination of two or more of them.

Examples of the anionic surfactant include a polyoxyethylene alkyl ether acetic acid, a polyoxyethylene alkyl sulfuric acid ester, an alkyl sulfuric acid ester, a polyoxyethylene alkyl ether sulfuric acid, an alkyl ether sulfuric acid, an alkyl benzene sulfonic acid, an alkyl phosphoric acid ester, a polyoxyethylene alkyl phosphoric acid ester, a polyoxyethylene sulfosuccinic acid, an alkyl sulfosuccinic acid, an alkyl naphthalene sulfonic acid, an alkyl diphenyl ether disulfonic acid, and salts thereof.

Examples of the cationic surfactant include an alkyl trimethyl ammonium salt, an alkyl dimethyl ammonium salt, an alkyl benzyl dimethyl ammonium salt, and an alkyl amine salt.

Examples of the ampholytic surfactant include an alkyl betaine and an alkyl amine oxide.

Examples of the nonionic surfactant include a polyoxyalkylene alkyl ether such as a polyoxyethylene alkyl ether, a sorbitan fatty acid ester, a glycerin fatty acid ester, a polyoxyethylene fatty acid ester, a polyoxyethylene alkyl amine, and an alkyl alkanol amide.

When the polishing composition contains a surfactant, the concentration (content) of the surfactant is preferably 0.01% by mass or more, more preferably 0.05% by mass or more relative to the total mass of the polishing composition. Further, the concentration (content) of the surfactant in the polishing composition is preferably 3.0% by mass or less, more preferably 2.0% by mass or less relative to the total mass of the polishing composition. When the concentration (content) of the surfactant is within the above range, polishing uniformity of an object to be polished is further improved.

### <Dispersing Agent/Thickening Agent (Viscosity Adjusting Gent)>

The polishing composition according to some embodiments of the present disclosure may contain a dispersing agent or a thickening agent (viscosity adjusting agent). The dispersing agent or the thickening agent plays a role in uniformly dispersing abrasive grains (alumina particles) in a liquid so that the abrasive grains can efficiently act on an object to be polished. Further, the presence of the dispersing agent or the thickening agent between abrasive grains is expected to have the function of preventing caking of the abrasive grains, which prevents the occurrence of scratching resulting from the aggregated abrasive grains.

Specific examples of the dispersing agent include colloidal substances containing fine particles, such as colloidal alumina, colloidal silica, colloidal zirconia, colloidal titania, alumina sol, silica sol, zirconia sol, titania sol, fumed alumina, fumed silica, fumed zirconia, and fumed titania. Alternatively, sodium phosphate, sodium hexametaphosphate, sodium pyrophosphate, or the like, which is commonly used as a dispersing agent, may be used.

Specific examples of the thickening agent include a glycol such as propylene glycol or a polymer thereof or ethylene glycol or a polymer thereof and a polymer compound. More specific examples of the glycol include propylene glycol, ethylene glycol, dipropylene glycol, polypropylene glycol, diethylene glycol, and polyethylene glycol. Examples of the polymer compound include sodium polyacrylate, polyvinyl alcohol, and hydroxyethyl cellulose.

### <Oxidizing Agent>

When an object to be polished contains a metallic material, the polishing composition according to some embodiments of the present disclosure may contain an oxidizing agent. The oxidizing agent has the function of hardening the surface of a metallic material due to oxidization to prevent the occurrence of defects such as scratching. Specific examples of the oxidizing agent include a peroxide such as hydrogen peroxide, a nitric acid salt, an iodic acid salt, a periodic acid salt, a hypochlorous acid salt, a chlorous acid salt, a chloric acid salt, a perchloric acid salt, a persulfuric acid salt, a dichromic acid salt, a permanganic acid salt, ozone water, a silver (II) salt, and an iron (III) salt. These oxidizing agents may be used singly or in combination of two or more of them. The oxidizing agent to be used may be a commercially-available product or a synthetic product.

### <Anticorrosive>

When an object to be polished contains a metallic material, the polishing composition according to some embodiments of the present disclosure may contain an anticorrosive. The anticorrosive has the function of preventing excessive dissolution of a metallic material. The anticorrosive may be, for example, a heterocyclic compound. The number of members in a heterocycle in the heterocyclic compound is not limited. The heterocyclic compound may be a monocyclic compound or a polycyclic compound having a condensed ring. These anticorrosives may be used singly or in combination of two or more of them. The anticorrosive to be used may be a commercially-available product or a synthetic product.

Specific examples of the heterocyclic compound that can be used as an anticorrosive include nitrogen-containing heterocyclic compounds such as a pyrrole compound, a pyrazole compound, an imidazole compound, a triazole compound, a tetrazole compound, a pyridine compound, a pyrazine compound, a pyridazine compound, a pyrindine compound, an indolizine compound, an indole compound, an isoindole compound, an indazole compound, a purine compound, a quinolizine compound, a quinoline compound, an isoquinoline compound, a naphthyridine compound, a phthalazine compound, a quinoxaline compound, a quinazoline compound, a cinnoline compound, a buterizine compound, a thiazole compound, an isothiazole compound, an oxazole compound, an isoxazole compound, and a furazan compound.

When the polishing composition contains an anticorrosive, the concentration (content) of the anticorrosive is preferably 0.001% by mass or more, more preferably 0.005% by mass or more, even more preferably 0.01% by mass or more relative to the total mass of the polishing composition. Further, the concentration (content) of the anticorrosive in the polishing composition is preferably 1.0% by mass or less, more preferably 0.5% by mass or less, even more preferably 0.1% by mass or less relative to the total mass of the polishing composition. When the concentration (content) of the anticorrosive is within the above range, the function of preventing excessive dissolution of a metallic material-containing object to be polished is further improved.

### <Antifungal Agent, Antiseptic Agent>

The polishing composition according to some embodiments of the present disclosure may contain an antifungal agent or an antiseptic agent. Specific examples of the antifungal agent or the antiseptic agent include an isothiazoline-based antiseptic agent (e.g., 2-methyl-4-isothiazolin-3-one, 5-chloro-2-methyl-4-isothiazolin-3-one), a paraoxybenzoic acid ester, and phenoxyethanol. These antifungal agents or antiseptic agents may be used singly or in combination of two or more of them.

### <Chelating Agent>

When an object to be polished contains a metallic material, it is preferred that the polishing composition according to some embodiments of the present disclosure contain substantially no chelating agent. This makes it possible to prevent an increase in defects such as scratching and dishing in the surface of the metallic material due to a chelating agent in the polishing composition. The “polishing composition contains substantially no chelating agent” herein means that a chelating agent is not at least intentionally added to the polishing composition, and therefore the concept includes not only a case where the polishing composition contains no chelating agent but also a case where the polishing composition contains a chelating agent in an amount of 0.1% by mass or less. The concentration (content) of the chelating agent is more preferably 0.05% by mass or less, even more preferably 0.01% by mass or less, particularly preferably 0% by mass relative to the total mass of the polishing composition. That is, it is particularly preferred that no chelating agent be contained. Examples of the chelating agent include an aminocarboxylic acid-based chelating agent and an organic phosphonic acid-based chelating agent.

### [Polishing Removal Rate]

The polishing composition according to some embodiments of the present disclosure may make it possible to increase the polishing removal rate of a resin material. The polishing removal rate of a resin material is, for example, preferably 0.8 μm/min or more, more preferably 1.0 μm/min or more, even more preferably 1.1 μm/min or more. It should be noted that the polishing removal rate is determined by a method that will be described in Examples.

### [Method for Producing Polishing Composition]

A method for producing (preparing) the polishing composition according to some embodiments of the present disclosure is not limited. For example, a production method can be appropriately used which includes mixing alumina particles, water, and other optional components with stirring. It should be noted that the alumina particles, the water, and the other components are the same as those described above, and therefore description thereof will not be repeated.

A temperature at which the components of the polishing composition are mixed is not limited, but is preferably 10° C. or more and 40° C. or less. In order to increase the rate of dissolution, heat may be applied. A mixing time is not limited, either.

### [Polishing Method]

A second embodiment of the present disclosure relates to a polishing method including the step of polishing an object to be polished with use of the polishing composition described above. Preferred examples of the object to be polished in the present embodiment are the same as those described above in [Object to be polished].

When an object to be polished is polished using the polishing composition, an apparatus and conditions commonly used for polishing can be used. Examples of such a common polishing apparatus include a single-side polishing apparatus and a double-side polishing apparatus. The single-side polishing apparatus generally polishes one surface of an object to be polished in such a manner that the object to be polished is held using a holding tool called a carrier, and a polishing table having a polishing pad attached thereto is pressed against one surface of the object to be polished and turned while a polishing composition is supplied from above. The double-side polishing apparatus generally polishes both surfaces of an object to be polished in such a manner that the object to be polished is held using a holding tool called a carrier, and polishing tables each having a polishing pad attached thereto are pressed against the surfaces of the object to be polished, which are opposed to each other, and turned in opposite directions while a polishing composition is supplied from above. At this time, the object to be polished is polished by a physical action due to friction between the polishing pad and the polishing composition and the object to be polished and a chemical action of the polishing composition on the object to be polished. As the polishing pad, a porous body such as nonwoven fabric, polyurethane, or swede can be used without limitation. The polishing pad is preferably subjected to processing so as to be able to hold a polishing liquid.

Examples of the polishing conditions include a polishing load, a polishing table rotation speed, a carrier rotation speed, a polishing composition flow rate, and a polishing time. These polishing conditions are not limited, but the polishing load is, for example, preferably 0.1 psi (0.69 kPa) or more and 10 psi (69 kPa) or less, more preferably 0.5 psi (3.5 kPa) or more and 8.0 psi (55 kPa) or less. In general, as a load increases, a friction force generated by abrasive grains increases and therefore mechanical processing power increases so that a polishing removal rate increases. When the polishing load is within the above range, a sufficient polishing removal rate is achieved and it is possible to prevent the breakage of an object to be polished due to a load and the occurrence of defects such as scratching in the surface of an object to be polished. The polishing table rotation speed and the carrier rotation speed are preferably 10 rpm (0.17 s⁻¹) or more and 500 rpm (8.3 s⁻¹) or less. The amount of the polishing composition to be supplied may be an amount to be supplied (flow rate) such that an object to be polished is entirely covered with the polishing composition, and may be adjusted according to conditions such as the size of the object to be polished. A method for supplying the polishing composition to the polishing pad is not limited, either and may be, for example, a method in which the polishing composition is continuously supplied by a pump or the like. Further, a processing time is not limited as long as a desired processing result is obtained, but is preferably shorter due to a high polishing removal rate.

A third embodiment of the present disclosure relates to a method for producing a polished object, the method including the step of polishing an object to be polished by the polishing method described above. Preferred examples of the object to be polished in the present embodiment are the same as those described above in [Object to be polished]. A preferred example of the method is a method for producing an electronic circuit board, the method including polishing an object to be polished containing a resin material by the polishing method described above.

The embodiments of the present disclosure have been described in detail but are merely illustrative and exemplary and not intended to limit the present disclosure, and it is apparent that the scope of the present disclosure should be interpreted by the appended claims.

The present disclosure includes the following aspects and modes:
[1] A polishing composition containing water and alumina particles, wherein the alumina particles have a bimodal volume-based particle size distribution;
[2] The polishing composition according to [1], wherein when, in the volume-based particle size distribution of the alumina particles,
   a peak on a smaller particle size side is defined as a first peak and
   a peak on a larger particle size side than the first peak is defined as a second peak,
   a ratio of a particle size PS2 at a peak top of the second peak to a particle size PS1 at a peak top of the first peak (PS2/PS1) is 1.3 or more and 3 or less;
[3] The polishing composition according to [2], wherein when
   a peak height of the first peak is defined as H1 and
   a peak height of the second peak is defined as H2,
   a ratio of the peak height H2 of the second peak to the peak height H1 of the first peak (H2/H1) is 0.1 or more and 1.0 or less;
[4] The polishing composition according to any one of [1] to [3], wherein when
   a BET specific surface area of the alumina particles is defined as SA and
   a particle size at which a cumulative frequency from a smaller particle size side in the volume-based particle size distribution of the alumina particles is 50% is defined as D₅₀ and a theoretical specific surface area calculated from the D₅₀ is defined as SA′,
   a non-sphericity N represented by the following formula (1) satisfies a relationship of the following formula (2):

$$\begin{matrix}[ Formula 4 ] & \\ Non - sphericity N = \frac{SA}{{SA}^{′}} & ( 1 )\end{matrix}$$

$$2 \leq N \leq 8 \qquad ( 2 )$$

[5] The polishing composition according to [4], wherein when, in the volume-based particle size distribution of the alumina particles,
   a particle size at which the cumulative frequency from a smaller particle size side is 2% is defined as D₂, and
   a particles size at which the cumulative frequency from a smaller particle size side is 98% is defined as D₉₈,
   a skewness S represented by the following formula (3) satisfies a relationship of the following formula (4):

$$\begin{matrix}[ Formula 5 ] & \\ Skewness S = \frac{( {D}_{50} / {D}_{2} )}{( {D}_{98} / {D}_{50} )} & ( 3 )\end{matrix}$$

$$0.5 \leq S \leq 1. \qquad ( 4 )$$

[6] The polishing composition according to [4] or [5], wherein the D₅₀ of the alumina particles is 0.50 μm or more and 0.90 μm or less;
[7] The polishing composition according to any one of [1] to [6], which has a pH of 7 or more and 14 or less;
[8] The polishing composition according to any one of [1] to [7], which is used for polishing an object to be polished containing a resin material;
[9] The polishing composition according to [8], wherein the resin material contains polyimide;
[10] The polishing composition according to [8] or [9], wherein the object to be polished further contains a metallic material;
[11] The polishing composition according to any one of [1] to [10], wherein the polishing composition contains substantially no chelating agent; and
[12] A polishing method including the step of polishing an object to be polished with use of the polishing composition according to any one of [1] to [11].

### EXAMPLES

Examples of the present disclosure will be described. However, the technical scope of the present disclosure is not limited only to the following examples. It should be noted that unless otherwise specified, “%” and “part(s)” refer to “% by mass” and “part(s) by mass”, respectively. The pH of a polishing composition was measured by a pH meter.

### Example 1

Alumina particles as abrasive grains and pure water were mixed and then appropriately subjected to grinding and classification. Then, polyoxyethylene decyl ether (average number of moles of oxyethylene group added: 7) was added as a surfactant in an amount such that a final concentration thereof was 0.05% by mass, and benzotriazole was added as an anticorrosive in an amount such that a final concentration thereof was 0.02% by mass. Then, the value of pH was adjusted to 10.5 using potassium carbonate as a pH adjusting agent to obtain a polishing composition 1 (mixing temperature: about 25° C., mixing time: about 30 minutes). The concentration of the alumina particles in the polishing composition 1 was 3% by mass.

### Example 2

Alumina particles as abrasive grains and pure water were mixed and then appropriately subjected to grinding and classification. Then, the value of pH was adjusted to 11.5 using potassium hydroxide as a pH adjusting agent to obtain a polishing composition 2 (mixing temperature: about 25° C., mixing time: about 30 minutes). The concentration of the alumina particles in the polishing composition 2 was 5% by mass.

### Example 3

A polishing composition 3 was obtained in the same manner as in Example 2 except that potassium hydroxide as a pH adjusting agent was not used (mixing temperature: about 25° C., mixing time: about 30 minutes). The concentration of the alumina particles in the polishing composition 3 was 5% by mass, and the pH value of the polishing composition 3 was 7.0.

### Comparative Examples 1 to 4

Alumina particles as abrasive grains and pure water were mixed and then appropriately subjected to grinding and classification. In this way, comparative polishing compositions 1 to 4 were obtained.

The physical properties of the alumina particles contained in each of the polishing compositions obtained above, a polishing removal rate at the time when a polyimide substrate was polished using each of the polishing compositions obtained above, and scratching in the surface of the polyimide substrate after polishing were evaluated.

### [Evaluations]

### <Peak(s) of Alumina Particles>

The alumina particles were measured using a laser diffraction particle size distribution measurement apparatus (manufactured by MicrotracBEL, Microtrac particle size distribution measurement apparatus MT3300EX II) to determine a volume-based particle size distribution. When the obtained particle size distribution was bimodal, a peak on a smaller particle size side was defined as a first peak and a peak on a larger particle size side than the first peak was defined as a second peak to determine a particle size PS1 at the peak top of the first peak, a peak height H1 of the first peak, a particle size PS2 at the peak top of the second peak, and a peak height H2 of the second peak. It should be noted that the volume-based particle size distribution of the alumina particles contained in each of the comparative polishing compositions 1 to 4 was monomodal.

<D₂, D₅₀, D₉₈ of Alumina Particles>

In each of the volume-based particle size distributions of the alumina particles obtained above, a particle size at which a cumulative frequency from a smaller particle size side was 2% was defined as D₂ of the alumina particles, a particle size at which a cumulative frequency from a smaller particle size side was 50% was defined as D₅₀ of the alumina particles, and a particle size at which a cumulative frequency from a smaller particle size side was 98% was defined as D₉₈ of the alumina particles.

### <BET Specific Surface Area of Alumina Particles>

The BET specific surface area SA of the alumina particles was measured using an automatic specific surface area measurement apparatus manufactured by Mountech Co., Ltd. (Macsorb® HM model-1201).

### <Theoretical Specific Surface Area SA′ of Alumina Particles>

The theoretical specific surface area SA′ of the alumina particles was calculated by the following formula (5) using the value of D₅₀ measured above.

$$\begin{matrix}[ Formula 6 ] & \\ Theoretical specific surface area {SA}^{′} = \frac{6}{ρ \times {D}_{50}} & ( 5 )\end{matrix}$$

In the above formula (5), ρ represents the density of the alumina particles and is defined as 3.95 g/cm³.

A non-sphericity N and a skewness S were respectively calculated by the following formula (1) and the following formula (3) using the values of D₂, D₅₀, D₉₈, SA, and SA′ obtained above.

$$\begin{matrix}[ Formula 7 ] & \\ Non - sphericity N = \frac{SA}{{SA}^{′}} & ( 1 )\end{matrix}$$

$$Skewness S = \frac{( {D}_{50} / {D}_{2} )}{( {D}_{98} / {D}_{50} )} \qquad ( 2 )$$

### <Evaluations of Polishing Removal Rate and Scratching>

A polyimide (PI) substrate was prepared as an object to be polished and was polished using each of the polishing compositions by the following polishing apparatus under the following polishing conditions. The object to be polished after polishing was evaluated for the polishing removal rate of polyimide in the following manner (Polishing removal rate evaluation method), and scratching in the surface of the polished polyimide substrate was evaluated in the following manner (Scratching evaluation method).

### (Object to be Polished)

Polyimide substrate: size 30 mm×30 mm (manufactured by Asahi Kasei Corp., trade name PIMEL BL301)

### (Polishing Apparatus and Polishing Conditions)

Polishing apparatus: small-sized tabletop polishing machine (manufactured by Engis Japan Corporation, EJ380 IN)

Polishing table diameter: 380 [mm]

Polishing pad: non-woven fabric pad (manufactured by Fujibo Ehime Co., Ltd., FP4)

Platen (polishing table) rotation speed: 50 [rpm]

Head (carrier) rotation speed: 50 [rpm]

Polishing pressure: 3.9 [psi] (274 [g/cm²], 270 kPa)

Flow rate of polishing composition: 80 [mL/min]

Polishing time: 1 [min]

### (Polishing Removal Rate Evaluation Method)

1. The mass of an object to be polished was measured using an analytical balance XS205 (manufactured by METTLER TOLEDO) before and after polishing, and from a difference between the measured masses, a mass change ΔM [kg] of the object to be polished before and after polishing was calculated.

2. The mass change ΔM [kg] of the object to be polished before and after polishing was divided by the specific gravity of the object to be polished (the specific gravity of a material to be polished) to calculate a volume change ΔV [m³] of the object to be polished before and after polishing.

3. The volume change ΔV [m³] of the object to be polished before and after polishing was divided by an area s [m²] of surface to be polished of the object to be polished to calculate a thickness change Δd [m] of the object to be polished before and after polishing.

4. The thickness change Δd [m] of the object to be polished before and after polishing was divided by a polishing time t [min], and the unit was converted to [μm/min]. The thus obtained value was defined as a polishing removal rate v [μm/min].

### (Scratching Evaluation Method)

The surface of the polyimide substrate after polishing was visually observed to evaluate scratching according to the following evaluation criteria.

Good: Scratching cannot be visually observed under fluorescent lights.

Poor: scratching can be visually observed under fluorescent lights.

The physical properties of the alumina particles contained in each of the polishing compositions are shown below in Table 1 and the configuration of each of the polishing compositions and the evaluation results are shown below in Table 2. It should be noted that “-” in Table 2 means that this component was not used.

TABLE 1

| | Particle Size Distribution | | | | | | | | | | | | | |
|---|---|---|---|---|---|---|---|---|---|---|---|---|---|---|
| | | | | | | | | | | | | Non- | | |
| | | First | | Second | | | | Skewness S | | | | sphericity N | | |
| | | Peak | | Peak | | | | | | | S | SA | SA′ | N |
| | Distri- | PS1 | | PS2 | | PS2/ | H2/ | D₉₈ | D₅₀ | D₂ | val- | [m²/ | [m²/ | val- |
| | bution | [μm] | H1 | [μm] | H2 | PS1 | H1 | [μm] | [μm] | [μm] | ue | g] | g] | ue |
| Exam- | Bi- | 0.53 | 5.4 | 1.06 | 4.2 | 2.00 | 0.79 | 2.50 | 0.69 | 0.24 | 0.8 | 13.6 | 2.2 | 6.2 |
| ple 1 | modal | | | | | | | | | | | | | |
| Exam- | Bi- | 0.53 | 5.4 | 1.06 | 4.2 | 2.00 | 0.79 | 2.50 | 0.69 | 0.24 | 0.8 | 13.6 | 2.2 | 6.2 |
| ple 2 | modal | | | | | | | | | | | | | |
| Exam- | Bi- | 0.53 | 5.4 | 1.06 | 4.2 | 2.00 | 0.79 | 2.50 | 0.69 | 0.24 | 0.8 | 13.6 | 2.2 | 6.2 |
| ple 3 | modal | | | | | | | | | | | | | |
| Com- | Mono- | — | — | — | — | — | — | 1.40 | 0.52 | 0.20 | 1.0 | 21.9 | 2.9 | 7.5 |
| par- | modal | | | | | | | | | | | | | |
| ative | | | | | | | | | | | | | | |
| Exam- | | | | | | | | | | | | | | |
| ple 1 | | | | | | | | | | | | | | |
| Com- | Mono- | — | — | — | — | — | — | 5.50 | 0.50 | 0.20 | 0.3 | 5.6 | 2.9 | 2.0 |
| par- | modal | | | | | | | | | | | | | |
| ative | | | | | | | | | | | | | | |
| Exam- | | | | | | | | | | | | | | |
| ple 2 | | | | | | | | | | | | | | |
| Com- | Mono- | — | — | — | — | — | — | 3.27 | 1.09 | 0.40 | 0.9 | 2.2 | 1.4 | 1.6 |
| par- | modal | | | | | | | | | | | | | |
| ative | | | | | | | | | | | | | | |
| Exam- | | | | | | | | | | | | | | |
| ple 3 | | | | | | | | | | | | | | |
| Com- | Mono- | — | — | — | — | — | — | 4.63 | 1.38 | 0.41 | 1.01 | 10.8 | 1.1 | 9.8 |
| par- | modal | | | | | | | | | | | | | |
| ative | | | | | | | | | | | | | | |
| Exam- | | | | | | | | | | | | | | |
| ple 4 | | | | | | | | | | | | | | |

TABLE 2

| | | | | | | | | | Evaluation | |
|---|---|---|---|---|---|---|---|---|---|---|
| | | Alumina | | | | | | | Results | |
| | | Particles | Surfactant | | Anticorrosive | | | | Polishing | |
| | Com- | Con- | | Con- | | Con- | pH | | Removal | |
| | position | centration | | centration | | centration | Adjusting | | Rate | |
| | No. | (mass %) | Type | (mass %) | Type | (mass %) | Agent | pH | [μm/min] | Scratching |
| Example 1 | 1 | 3 | Poly - | 0.05 | Benzo- | 0.02 | Potassium | 10.5 | 0.8 | Good |
| | | | oxyethylene | | triazole | | Carbonate | | | |
| | | | Decyl | | | | | | | |
| | | | Ether | | | | | | | |
| Example 2 | 2 | 5 | — | — | — | — | Potassium | 11.5 | 1.2 | Good |
| | | | | | | | Hydroxide | | | |
| Example 3 | 3 | 5 | — | — | — | — | — | 7.0 | 1.0 | Good |
| Comparative | Com- | 5 | — | — | — | — | — | 7.0 | 0.6 | Good |
| Example 1 | parative 1 | | | | | | | | | |
| Comparative | Com- | 5 | — | — | — | — | — | 7.0 | 0.4 | Good |
| Example 2 | parative 2 | | | | | | | | | |
| Comparative | Com- | 5 | — | — | — | — | — | 7.0 | 0.3 | Good |
| Example 3 | parative 3 | | | | | | | | | |
| Comparative | Com- | 5 | — | — | — | — | — | 7.0 | 1.1 | Poor |
| Example 4 | parative 4 | | | | | | | | | |

As can be seen from Table 2, the polishing compositions of Examples can achieve a high polishing removal rate of polyimide and can reduce scratching in the surface of the polyimide substrate after polishing, but on the other hand, the polishing compositions of Comparative Examples are inferior to the polishing compositions of Examples in either of the polishing removal rate of polyimide or scratching in the surface of the polyimide substrate after polishing.

This application is based on Japanese Patent Application No. 2025-055779 filed on Mar. 28, 2025, the disclosure of which is incorporated herein by reference in its entirety.

1. A polishing composition comprising
water; and
alumina particles, wherein
the alumina particles have a bimodal volume-based particle size distribution.

2. The polishing composition according to claim 1, wherein when, in the volume-based particle size distribution of the alumina particles,
a peak on a smaller particle size side is defined as a first peak, and
a peak on a larger particle size side than the first peak is defined as a second peak,
a ratio of a particle size PS2 at a peak top of the second peak to a particle size PS1 at a peak top of the first peak (PS2/PS1) is 1.3 or more and 3 or less.

3. The polishing composition according to claim 2, wherein when
a peak height of the first peak is defined as H1, and
a peak height of the second peak is defined as H2,
a ratio of the peak height H2 of the second peak to the peak height H1 of the first peak (H2/H1) is 0.1 or more and 1.0 or less.

4. The polishing composition according to claim 1, wherein when
a BET specific surface area of the alumina particles is defined as SA, and
a particle size at which a cumulative frequency from a smaller particle size side in the volume-based particle size distribution of the alumina particles is 50% is defined as D₅₀ and a theoretical specific surface area calculated from the D₅₀ is defined as SA′,
a non-sphericity N represented by the following formula (1) satisfies a relationship of the following formula (2):
$$\begin{matrix}[ Formula 1 ] & \\ Non - sphericity N = \frac{SA}{{SA}^{′}} & ( 1 )\end{matrix}$$
$$2 \leq N \leq 8 \qquad ( 2 )$$

5. The polishing composition according to claim 4, wherein when, in the volume-based particle size distribution of the alumina particles,
a particle size at which the cumulative frequency from a smaller particle size side is 2% is defined as D₂, and
a particle size at which the cumulative frequency from a smaller particle size side is 98% is defined as D₉₈,
a skewness S represented by the following formula (3) satisfies a relationship of the following formula (4):
$$\begin{matrix}[ Formula 2 ] & \\ Skewness S = \frac{( {D}_{50} / {D}_{2} )}{( {D}_{98} / {D}_{50} )} & ( 3 )\end{matrix}$$
$$0.5 \leq S \leq 1. \qquad ( 4 )$$

6. The polishing composition according to claim 4, wherein the D₅₀ of the alumina particles is 0.5 μm or more and 0.9 μm or less.

7. The polishing composition according to claim 1, which has a pH of 7 or more and 14 or less.

8. The polishing composition according to claim 1, which is used for polishing an object to be polished containing a resin material.

9. The polishing composition according to claim 8, wherein the resin material contains polyimide.

10. The polishing composition according to claim 8, wherein the object to be polished further contains a metallic material.

11. The polishing composition according to claim 1, wherein the polishing composition comprises substantially no chelating agent.

12. A polishing method comprising the step of polishing an object to be polished with use of the polishing composition according to claim 1.
